(19) United States
(12) Patent Application Publication
(10) Pub. No.: US 2026/0130274 A1
(43) Pub. Date: May 7, 2026

(54) ELECTRONIC PACKAGE MODULE AND METHOD FOR FABRICATION OF THE SAME

(71) Applicant: Universal Global Technology (Kunshan) Co., Ltd., Jiangsu Province (CN)

(72) Inventors: TSUNG-YUEH TSAI, Jiangsu Province (CN); CHEN CHENG OU, Jiangsu Province (CN)

(21) Appl. No.: 19/021,775

(22) Filed: Jan. 15, 2025

(30) Foreign Application Priority Data
Nov. 6, 2024 (CN) 202411572372.1

(51) Int. Cl. H01L 23/31; H01L 21/48; H01L 21/56; H01L 23/373; H01L 23/552; H01L 25/18

(52) U.S. Cl. CPC H10W 74/124; H10W 40/037; H10W 40/255; H10W 42/20; H10W 74/01; H10W 90/00

(57) ABSTRACT

An electronic package module includes a circuit substrate, an electronic component and an encapsulation layer on the circuit substrate, a thermal conductive material inside a cavity of the encapsulation layer and a heat sink on the thermal conductive material. The electronic component has a top surface facing away from the circuit substrate is electronically connected to the circuit substrate. The encapsulation layer encapsulates the electronic component. The bottom surface of the cavity exposes the top surface of the electronic component. The thermal conductive material is at the top surface of the electronic component and has a first surface of the electronic component far away from the electronic component. The encapsulation layer has a second surface far away from the circuit substrate. The first surface is flush with the second surface. The thermal conductive material is between the electronic component and the heat sink.

### RELATED APPLICATIONS

This application claims priority to China Application Serial Number 202411572372.1, filed Nov. 6, 2024, which is herein incorporated by reference in its entirety.

### BACKGROUND

### Technical Field

The present disclosure relates to an electronic package module and the method for fabrication of the same.

### Description of Related Art

With the development of electronic products having diverse functions, the electronic package modules in the electronic products require to accommodate more and more electronic components. Thus, the demand for heat dissipation of the electronic package modules increases. In the electronic package modules with high heat dissipation requirements, the backsides of electronic components that generate more heat (e.g., transistors) are exposed to improve the heat dissipation efficiency.

Generally, there are two methods for the backsides of the electronic components to be exposed. The first one is to form concave and convex structures on the mold of the encapsulation process, so that a part of the mold is able to shield and touch the backsides of the electronic components. As a result, the encapsulation material does not cover the backsides of the electronic components. However, if the heights of the electronic components in the electronic package module are inconsistent, different molds are required for the first method, and thereby increasing the costs of fabrication. The second method is to grind or cut the encapsulation material of the electronic package module to expose the backsides of the electronic components. However, the second method is unable to be used under the situation that the height of the electronic components to be exposed is lower than the height of other electronic components.

### SUMMARY

Accordingly, the disclosure is to provide an electronic package module which is helpful to increase the heat dissipation efficiency.

At least one embodiment of the disclosure provides a method for fabricating the aforementioned electronic package module.

At least one embodiment of the disclosure provides an electronic package module including a circuit substrate, a first electronic component, an encapsulation layer, a thermal conductive material and a heat sink. The first electronic component is disposed on and electrically connected to the circuit substrate, and the first electronic component includes a first top surface facing away from the circuit substrate. The encapsulation layer is disposed on the circuit substrate and encapsulates the first electronic component. The encapsulation layer includes a cavity located on the first electronic component, and a bottom surface of the cavity exposes the first top surface of the first electronic component. The thermal conductive material is disposed inside the cavity of the encapsulation layer and located at the first top surface of the first electronic component. The thermal conductive material includes a first surface far away from the first electronic component, and the encapsulation layer includes a second surface far away from the circuit substrate. The first surface is flush with the second surface. The heat sink is disposed on the first surface of the thermal conductive material, and the thermal conductive material is located between the first electronic component and the heat sink.

At least one embodiment of the disclosure provides a method for fabricating an electronic package module including providing an initial circuit substrate. The method includes disposing an electronic component on the initial circuit substrate. The method includes disposing a releasing material on a top surface of the electronic component after the electronic component is disposed, and the releasing material touches the top surface directly. The method includes forming an initial encapsulation layer on the initial circuit substrate, so that the initial encapsulation layer encapsulates the electronic component and the releasing material. The initial encapsulation layer includes a first surface far away from the initial circuit substrate, and the releasing material includes a second surface far away from the initial circuit substrate. The first surface exposes the second surface, and the first surface is flush with the second surface. The method includes removing the releasing material to form a cavity after the initial encapsulation layer is formed, and the top surface of the electronic component is exposed. The method includes cutting the initial circuit substrate and the initial encapsulation layer to form a circuit substrate and an encapsulation layer after the cavity is formed. The method includes disposing a thermal conductive material inside the cavity. The method includes disposing a heat sink on the thermal conductive material, and the thermal conductive material is located between the heat sink and the electronic component.

According to the aforementioned embodiments, the top surface of the electronic component is exposed on the bottom surface of the cavity of the encapsulation layer, and the thermal conductive material with heat transfer coefficient between 1 W/mK and 200 W/mK is disposed between the top surface and the heat sink. Therefore, the heat transfer efficiency between the electronic component and the heat sink may increase.

### BRIEF DESCRIPTION OF THE DRAWINGS

To illustrate more clearly the aforementioned and the other features, merits, and embodiments of the present disclosure, the description of the accompanying figures are as follows:

FIG. 1 illustrates cross-sectional view of an electronic package in accordance with one embodiment of the present disclosure.

FIG. 2 illustrates a cross-sectional view of an electronic package in accordance with another embodiment of the present disclosure.

FIG. 3A to FIG. 3F illustrate cross-sectional views of a method for fabricating an electronic package module in accordance with one embodiment of the present disclosure.

### DETAILED DESCRIPTION

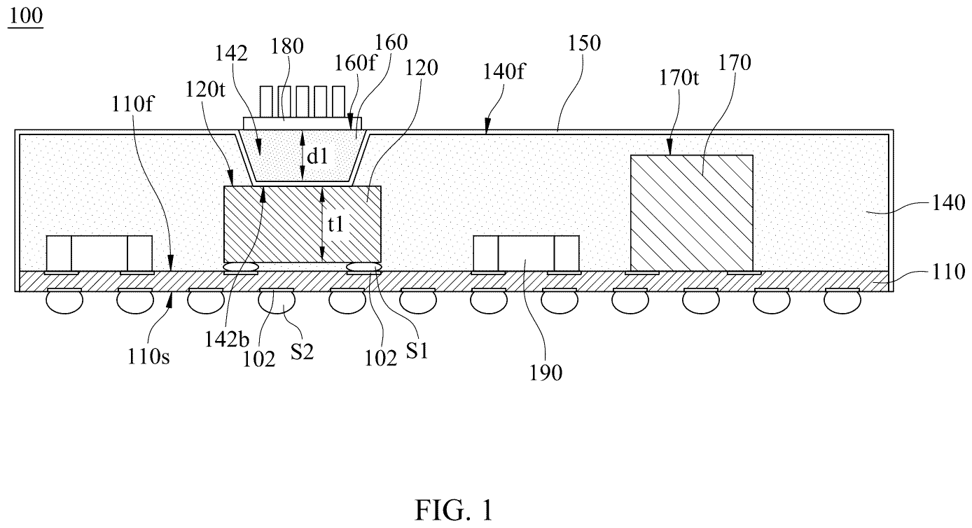

Referring to FIG. 1, an electronic package module 100 of at least one embodiment is disclosed. The electronic package module 100 includes a circuit substrate 110, an electronic component 120, an encapsulation layer 140, a thermal conductive material 160 and a heat sink 180. The electronic component 120 is disposed on and electrically connected to the circuit substrate 110. Specifically, the circuit substrate 110 includes a plurality of pads 102 which are located at a surface 110f. The electronic component 120 may be disposed on the pads 102 so as to be electrically connected to the circuit substrate 110 via the pads 102. The electronic component 120 may be packaged as a chip or unpackaged as a die.

In addition, a plurality of soldering structures S1, such as solder balls, copper pillars or other electrical connections are disposed on the electronic component 120. The soldering structures S1 are connected to the pads 102 separately, so that the electronic component 120 may be electrically connected to the circuit substrate 110 via the soldering structures S1. Furthermore, the circuit substrate 110 may include at least one solder mask (not shown), and the solder mask may cover the surface 110f of the circuit substrate 110 and expose the pads 102.

It is worth mentioning, the electronic component 120 has a top surface 120t facing away from the circuit substrate 110. The electronic component 120 in the embodiment is disposed on the circuit substrate 110 by but not limited to flip chip. In other embodiment, the electronic component 120 may be disposed on the circuit substrate 110 by wire-bonding.

In the embodiment, the electronic package module 100 further includes an electronic component 170 and an electronic component 190, while the electronic component 170 and the electronic component 190 are disposed on the circuit substrate 110. The electronic component 120 may be an active component such as a transistor, while the electronic component 170 and the electronic component 190 may be passive components, such as capacitors or inductors. However, the categories of the electronic component 120, the electronic component 170 and the electronic component 190 are not limited to the embodiment. In addition, the quantity of the electronic component 120, the electronic component 170 and the electronic component 190 of the disclosure is not limited to the embodiment. Specifically, the quantity of the electronic component 120 may be more than one (e.g., two electronic components 120), while the quantity of the electronic component 170 or the electronic component 190 may be more than zero.

It is worth mentioning, the electronic component 170 has a top surface 170t facing away from the circuit substrate 110 in the embodiment, and the top surface 170t may protrude from the top surface 120t of the electronic component 120. In other words, the top surface 170t of the electronic component 170 is above the top surface 120t of the electronic component 120 over the surface 110f of the circuit substrate 110.

The encapsulation layer 140 is disposed on the circuit substrate 110 and encapsulates the electronic component 120. However, the encapsulation layer 140 does not encapsulate the electronic component 120 entirely. As shown in FIG. 1, the encapsulation layer 140 includes a cavity 142 located at the electronic component 120, while a bottom surface 142b of the cavity 142 exposes the top surface 120t of the electronic component 120. The encapsulation layer 140 further covers a part of the top surface 120t of the electronic component 120. In addition, the encapsulation layer 140 covers the top surface 170t of the electronic component 170 entirely. The encapsulation layer 140 may include insulation materials, such as organic resins (e.g., epoxy resins) or other similar materials.

It is worth mentioning, a depth d1 of the cavity 142 of the encapsulation layer 140 may be larger than a thickness t1 of the electronic component 120 in some embodiments. Furthermore, the depth d1 of the cavity 142 may be between 0.5 and 5.0 the size of the thickness t1 of the electronic component 120. However, the ratio of the thickness t1 of the electronic component 120 and the depth d1 of the cavity 142 of the encapsulation layer 140 is not limited to the embodiment. That is, in other embodiments, the thickness t1 of the electronic component 120 may be smaller than or equal to the depth d1 of the cavity 142.

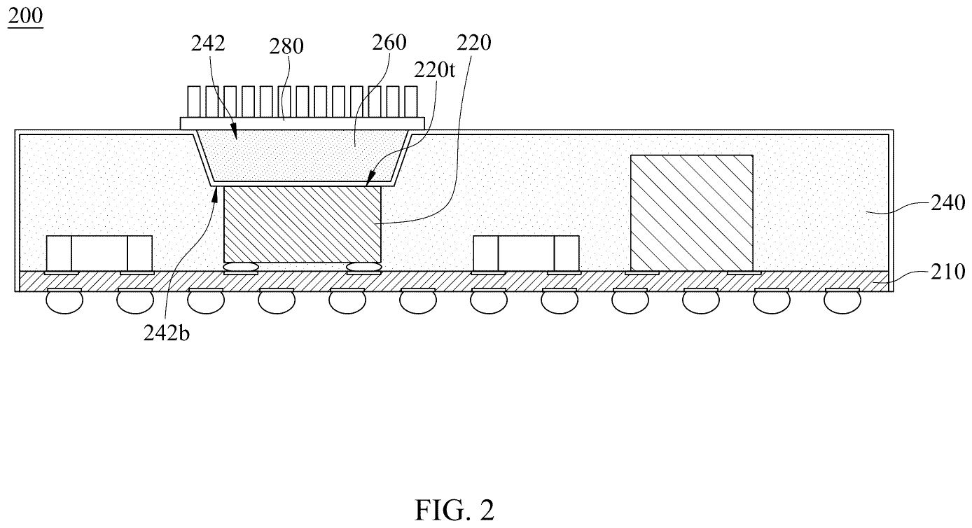

In the embodiment of FIG. 1, the area of the bottom surface 142b of the cavity 142 is smaller than the area of the top surface 120t of the electronic component 120, but the disclosure is not limited to the embodiment. The area of the bottom surface 142b of the cavity 142 may be larger than or equal to the area of the top surface 120t of the electronic component 120. For example, referring to an electronic package module 200 of another embodiment in FIG. 2. The electronic package module 200 is similar to the electronic package module 100 and includes a circuit substrate 210, an electronic component 220, an encapsulation layer 240, a thermal conductive material 260 and a heat sink 280. The difference between the electronic package module 100 and the electronic package module 200 is that the area of a bottom surface 242b of a cavity 242 is larger than the area of a top surface 220t of the electronic component 220 in the electronic package module 200.

Referring to FIG. 1, the thermal conductive material 160 is disposed inside the cavity 142 of the encapsulation layer 140 and is located at the top surface 120t of the electronic component 120. The thermal conductive material 160 has a surface 160f facing away from the electronic component 120, while the encapsulation layer 140 has a surface 140f facing away from the circuit substrate 110. The surface 160f of the thermal conductive material 160 is flush with the surface 140f of the encapsulation layer 140. Specifically, the cavity 142 of the encapsulation layer 140 is filled with the thermal conductive material 160 without any protrusion from the opening of the cavity 142 in the embodiment.

The thermal conductive material 160 includes thermal interface materials (TIM), such as thermal conductive pastes, thermal conductive films and thermal conductive adhesives, while the heat transfer coefficients of those thermal interface materials may be between 1 W/mK and 200 W/mK. Since the thermal conductive material 160 is located above the top surface 120t of the electronic component 120, the heat from the electronic component 120 is prone to being transferred to the side which is far away from the circuit substrate 110 (i.e., being transferred upward).

In addition, the electronic package module 100 further includes a metal layer 150. The metal layer 150 is disposed on the encapsulation layer 140 and covers the electronic component 120 and the encapsulation layer 140. The metal layer 150 is electrically connected to the circuit substrate 110, so that the electronic component 120 (and the electronic component 170 and the electronic component 190) in the electronic package module 100 may be electromagnetically shielded from the external environment of the electronic package module 100. Specifically, the metal layer 150 may cover the side surface (not denoted) of the encapsulation layer 140 and extend to the circuit substrate 110 so as to be electrically connected to the ground layer (not shown) of the circuit substrate 110. However, the disclosure is not limited to the embodiment. In other embodiments, the electronic package module 100 may exclude the metal layer 150.

It is worth mentioning, a part of the metal layer 150 is located between the electronic component 120 and the thermal conductive material 160, while this part of the metal layer 150 touches the top surface 120t of the electronic component 120 and the thermal conductive material 160 directly. The materials of the metal layer 150 may include metals with high heat transfer coefficients, such as stainless steel, copper and titanium. Thus, the heat from the electronic component 120 is prone to being transferred to the thermal conductive material 160 when the metal layer 150 touches the electronic component 120 and the thermal conductive material 160 directly.

The heat sink 180 is disposed on the surface 160f of the thermal conductive material 160, while the thermal conductive material 160 is located between the electronic component 120 and the heat sink 180. The heat sink 180 may be thermal dissipation structures such as finned heat sink, while the materials of the heat sink 180 may include metals, such as copper, aluminum or alloys thereof. The heat sink 180 may touch the surface 160f of the thermal conductive material 160 directly in some embodiments, while the heat sink 180 may be adhered to the surface 160f of the thermal conductive material 160 through the adhesive material (not shown) in other embodiments. The thinner the thickness of the aforementioned adhesive material is, the higher heat transfer between the thermal conductive material 160 and the heat sink 180 may be achieved.

The electronic package module 100 further includes a plurality of the soldering structures S2 which are disposed on a surface 110s of the circuit substrate 110 (via the pads 102). The surface 110f and the surface 110s of the circuit substrate 110 are located at two opposite sides of the circuit substrate 110 separately. The electronic package module 100 may be electrically connected to other components outside the electronic package module 100, such as a main board, via the soldering structures S2.

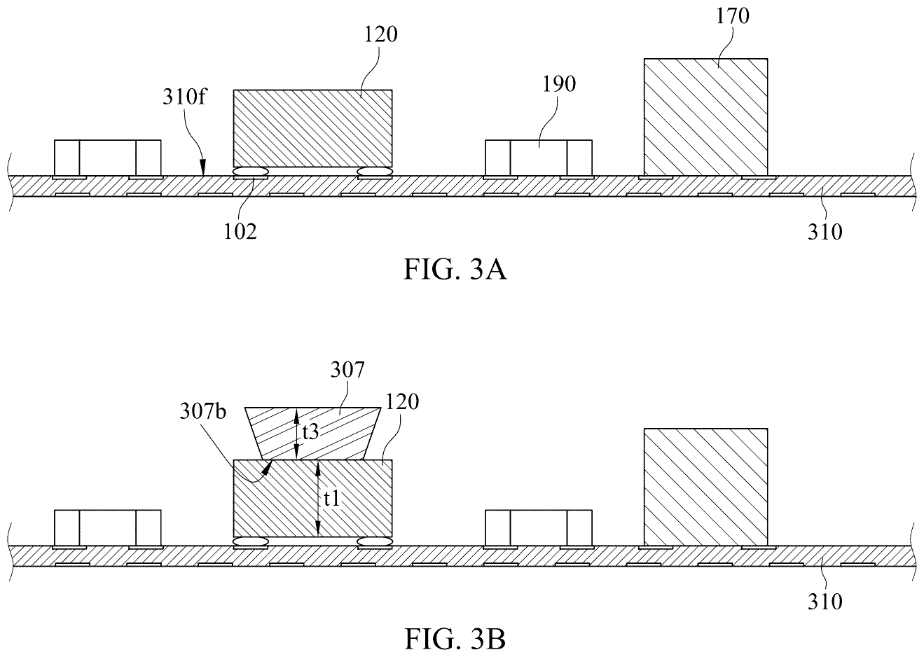

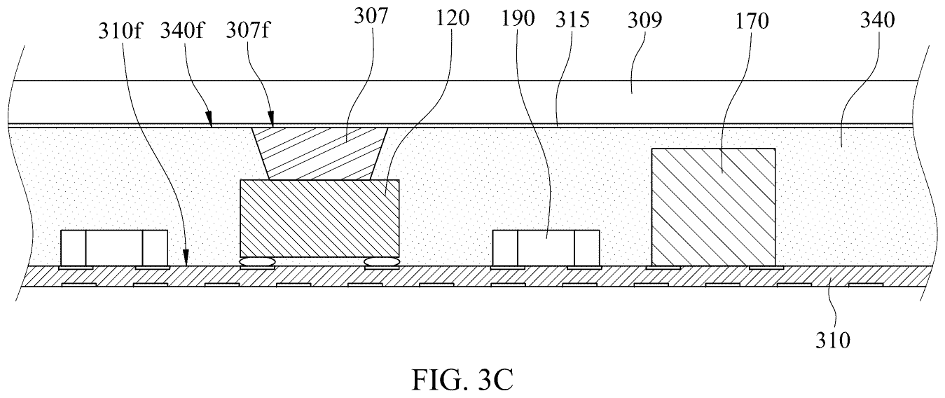

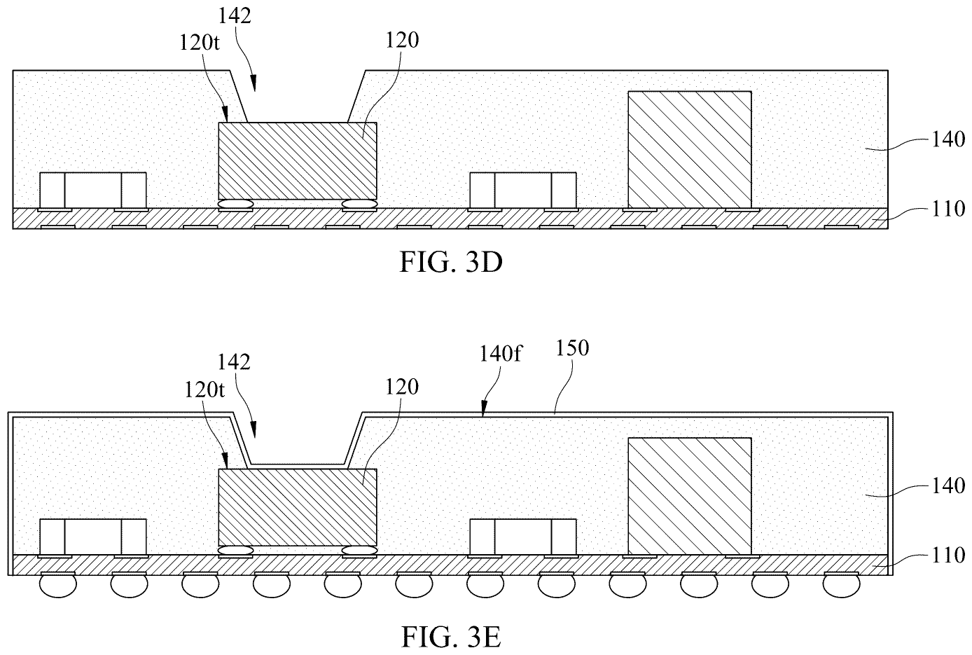

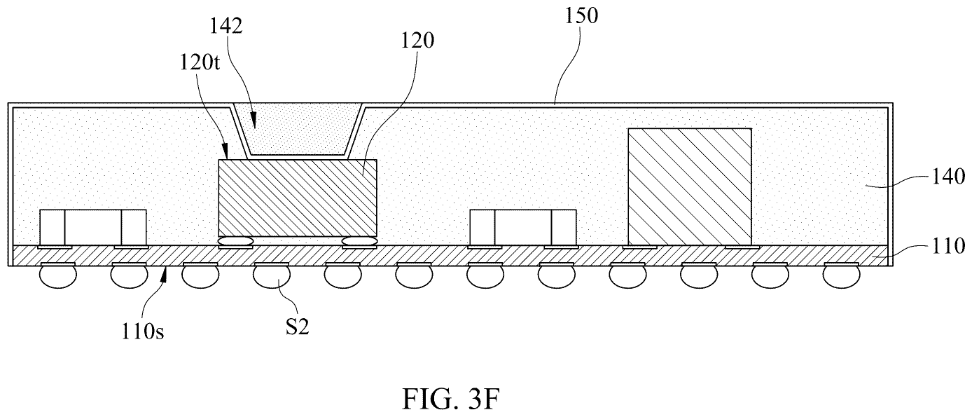

A method for fabrication of the electronic package module 100 is disclosed, while FIG. 3A to FIG. 3F illustrate sequent steps of the method in accordance with at least one embodiment of present disclosure. Referring to FIG. 3A, firstly, an initial circuit substrate 310 is provided. The initial circuit substrate 310 includes a surface 310f and the plurality of pads 102 exposed on the surface 310f. Next, the electronic component 120 is disposed on the initial circuit substrate 310 through the method such as soldering. That is, the electronic component 120 is connected to the pads 102 of the initial circuit substrate 310 through the soldering structures S1, so that the electronic component 120 is electrically connected to the initial circuit substrate 310. In addition, the step further includes disposing the electronic component 170 and the electronic component 190 on the initial circuit substrate 310 (on the pads 102 of the initial circuit substrate 310).

Referring to FIG. 3B, a releasing material 307 is disposed on the top surface 120t of the electronic component 120 after the electronic component 120 (and the electronic component 170 and the electronic component 190) are disposed. The releasing material 307 may include polysiloxanes, such as silicone. It is worth mentioning, the releasing material 307 touches the top surface 120t of the electronic component 120 directly. In the embodiment, the area of a bottom surface 307b of the releasing material 307 is smaller than the top surface 120t of the electronic component 120, while the thickness t3 of the releasing material 307 is smaller than the thickness t1 of the electronic component 120. However, the disclosure is not limited to the embodiment. The dimension (including the area of the bottom surface or the thickness) of the releasing material 307 may be modified in accordance with the requirement of the heat dissipation of the electronic package module 100 in various embodiments.

In addition, the shape of the releasing material 307 is not limited to be a frustum (a trapezoid in cross-sectional view). The releasing material 307 may be various three dimensional shapes, such as a cube, a cone or a triangular prism. Among the three dimensional shapes, the area of a surface 307f (denoted in FIG. 3C) is larger than or equal to the area of the bottom surface 307b of the releasing material 307. As a result, the releasing material 307 is more easily to be removed in subsequent steps.

An encapsulation layer 340 is formed on the initial circuit substrate 310 after the releasing material 307 is disposed, so that the encapsulation layer 340 encapsulates the electronic component 120 and the releasing material 307. Specifically, as shown in FIG. 3C, a mold 309 is disposed on the releasing material 307, while the mold 309 covers the initial circuit substrate 310, the electronic component 120, the electronic component 170, the electronic component 190 and the releasing material 307. It is worth mentioning, a protective film 315 is disposed between the mold 309 and the releasing material 307, and the protective film 315 may be a cushion between the mold 309 and the releasing material 307. The protective film 315 may be a polyimide (PI) film or a similar polymer film.

Next, the spacing between the surface 310f of the initial circuit substrate 310 and the mold 309 is filled up with an encapsulation material (not denoted), and the encapsulation material encapsulates the electronic component 120, the electronic component 170, the electronic component 190 and the releasing material 307. When the encapsulation material is cured, the encapsulation layer 340 is formed on the initial circuit substrate 310. The encapsulation layer 340 has a surface 340f which is far away from the initial circuit substrate 310, while the releasing material 307 has the surface 307f which is far away from the initial circuit substrate 310. The surface 340f of the encapsulation layer 340 exposes the surface 307f of the releasing material 307, and the surface 340f is flush with the surface 307f.

Referring to FIG. 3D, the mold 309 and the protective film 315 are removed after the encapsulation layer 340 is formed. It is worth mentioning, the protective film 315 may be an adhesive film (e.g., a polyimide adhesive tape) and adhered to the releasing material 307. As a result, the releasing material 307 will be removed along with the protective film 315 when the protective film 315 is removed. Thus, the cavity 142 is formed, so that the top surface 120t of the electronic component 120 is exposed.

After the cavity 142 is formed, the initial circuit substrate 310 and the encapsulation layer 340 may be cut by methods, such as machine cutting, laser cutting or focus ion beam cutting, so as to form the circuit substrate 110 and the encapsulation layer 140 shown in FIG. 1.

Referring to FIG. 3E, the steps of the embodiment further include depositing the metal layer 150 on the encapsulation layer 140 by the physical vapor deposition (e.g., sputtering) after the circuit substrate 110 and the encapsulation layer 140 are formed. Thus, the metal layer 150 covers the encapsulation layer 140 (i.e., covers the surface 140f and the side surface of the encapsulation layer 140) and the top surface 120t of the electronic component 120, so that a part of the metal layer 150 is distributed in the inner side of the cavity 142.

Next, referring to FIG. 3F, the thermal conductive material 160 is disposed inside the cavity 142. The thermal conductive material 160 is disposed on the metal layer 150 which is inside the cavity 142. That is, a part of the metal layer 150 inside the cavity 142 is located between the electronic component 120 and the thermal conductive material 160.

Next, the heat sink 180 (shown in FIG. 1) is disposed on the thermal conductive material 160, and the thermal conductive material 160 is located between the heat sink 180 and the electronic component 120. It is worth mentioning, the steps of the embodiment further include disposing the soldering structures S2 on the surface 110s of the circuit substrate 110 by pre-soldering. The soldering structures S2 are disposed on the circuit substrate 110 before the metal layer 150 is formed, but the disclosure is not limited to the embodiment. In other embodiments, the soldering structures S2 may be disposed on the circuit substrate 110 after the metal layer 150 is formed. Consequently, the electronic packaging module 100 as shown in FIG. 1 has been substantially completed.

Accordingly, in at least one embodiment of the disclosure, the top surface of the electronic component is exposed on the bottom surface of the cavity of the encapsulation layer, and the thermal conductive material with heat transfer coefficient between 1 W/mK and 200 W/mK is disposed between the top surface and the heat sink. Therefore, the heat transfer efficiency between the electronic component and the heat sink may increase.

Moreover, the releasing material is disposed on the top surface of the electronic component before the encapsulation layer is formed. Afterwards, the encapsulation layer encapsulating the electronic component is formed. As a result, the cavity can be formed on the top surface of the electronic component and expose the top surface of the electronic component without cutting, grinding or drilling after the releasing material is removed. In addition, there will be no interaction of bonding between the releasing material and the encapsulation layer (including the epoxy resin) since the releasing material includes polysiloxanes, such as silicone. Therefore, it is unnecessary to dispose a releasing layer (e.g., thermal release tape) between the releasing material and the encapsulation layer. In the process of removing the releasing material, the removal steps, such as thermal pyrolysis or UV photolysis, can be omitted, thereby reducing the cost of fabrication of the electronic packaging components.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. An electronic package module, comprising:
a circuit substrate;
a first electronic component disposed on and electrically connected to the circuit substrate, wherein the first electronic component comprises a first top surface facing away from the circuit substrate;
an encapsulation layer disposed on the circuit substrate and encapsulating the first electronic component, wherein the encapsulation layer comprises a cavity located on the first electronic component, and a bottom surface of the cavity exposes the first top surface of the first electronic component;
a thermal conductive material disposed inside the cavity of the encapsulation layer and located at the first top surface of the first electronic component, wherein the thermal conductive material comprises a first surface far away from the first electronic component, and the encapsulation layer comprises a second surface far away from the circuit substrate, wherein the first surface is flush with the second surface; and
a heat sink disposed on the first surface of the thermal conductive material, and the thermal conductive material is located between the first electronic component and the heat sink.

2. The electronic package module of claim 1, wherein a depth of the cavity is larger than a thickness of the first electronic component.

3. The electronic package module of claim 2, wherein the depth of the cavity is between 0.5 and 5.0 the size of the thickness of the first electronic component.

4. The electronic package module of claim 1, wherein an area of the bottom surface of the cavity is larger than an area of the first top surface of the first electronic component.

5. The electronic package module of claim 1, further comprising:
a metal layer disposed on the encapsulation layer and covering the first electronic component and the encapsulation layer, wherein a part of the metal layer is located between the first electronic component, and the thermal conductive material, and the part of the metal layer touches the first top surface of the first electronic component and the thermal conductive material directly, wherein the metal layer is electrically connected to the circuit substrate.

6. The electronic package module of claim 1, wherein the thermal conductive material comprises a thermal interface material.

7. The electronic package module of claim 1, further comprising:
a second electronic component disposed on the circuit substrate, wherein the second electronic component comprises a second top surface far away from the circuit substrate, and the second top surface protrudes from the first top surface of the first electronic component, wherein the encapsulation layer covers the second top surface of the second electronic component.

8. A method for fabricating an electronic package module, comprising:
providing an initial circuit substrate;
disposing an electronic component on the initial circuit substrate;
disposing a releasing material on a top surface of the electronic component after the electronic component is disposed, wherein the releasing material touches the top surface directly;
forming an initial encapsulation layer on the initial circuit substrate, so that the initial encapsulation layer encapsulates the electronic component and the releasing material, wherein the initial encapsulation layer comprises a first surface far away from the initial circuit substrate, and the releasing material comprises a second surface far away from the initial circuit substrate, wherein the first surface exposes the second surface, and the first surface is flush with the second surface;
removing the releasing material to form a cavity after the initial encapsulation layer is formed, and the top surface of the electronic component is exposed;
cutting the initial circuit substrate and the initial encapsulation layer to form a circuit substrate and an encapsulation layer after the cavity is formed;
disposing a thermal conductive material inside the cavity; and
disposing a heat sink on the thermal conductive material, wherein the thermal conductive material is located between the heat sink and the electronic component.

9. The method of claim 8, wherein the releasing material comprises polysiloxanes.

10. The method of claim 8, further comprising:
depositing a metal layer on the encapsulation layer after the circuit substrate and the encapsulation layer are formed, so that the metal layer covers the encapsulation layer and the top surface of the electronic component;
wherein the metal layer is electrically connected to the circuit substrate;
wherein a part of the metal layer is located between the electronic component and the thermal conductive material.
